(19) United States
(12) Patent Application Publication
(10) Pub. No.: US 2026/0150767 A1
(43) Pub. Date: May 28, 2026

(54) MANUFACTURING METHOD OF SEMICONDUCTOR DEVICE

(71) Applicant: National Yang Ming Chiao Tung University, Hsinchu City (TW)

(72) Inventors: Kuan-Neng CHEN, Hsinchu City (TW); Yu-Lun LIU, Kaohsiung City (TW); Chien-Kang HSIUNG, Taipei City (TW); Mu-Ping HSU, Hsinchu City (TW); Shie-Ping CHANG, Tainan City (TW)

(21) Appl. No.: 19/026,518

(22) Filed: Jan. 17, 2025

(30) Foreign Application Priority Data
Nov. 22, 2024 (TW) 113145228

(51) Int. Cl. H01L 23/00

(52) U.S. Cl. CPC H10W 99/00; H10W 80/312; H10W 80/327

(57) ABSTRACT

A manufacturing method of a semiconductor device includes: providing a first wafer including a first dielectric layer, a first metal layer in the first dielectric layer, and a first optical element in the first dielectric layer, in which a portion of the first metal layer and a portion of the first optical element are exposed through the first dielectric layer; providing a second wafer including a substrate, a second dielectric layer over the substrate, and a second metal layer in the second dielectric layer, in which a portion of the second metal layer is exposed through the second dielectric layer; and docking the first wafer and the second wafer, such that the first dielectric layer is bonded to the second dielectric layer, the first metal layer is bonded to the second metal layer, and the first optical element is bonded to the second dielectric layer.

### CROSS-REFERENCE TO RELATED APPLICATION

This application claims priority to Taiwan Application Serial Number 113145228, filed Nov. 22, 2024, which is herein incorporated by reference in its entirety.

### BACKGROUND

### Field of Disclosure

The present disclosure relates to a manufacturing method of a semiconductor device.

### Description of Related Art

With advancements in process technology, the demand for higher data transmission and computation rates has increased. The industry now faces the challenge of integrating increasingly complex circuits into a unit area during semiconductor fabrication. However, the data transmission bandwidth of traditional electronic integrated circuits is limited. Therefore, how to integrate optical elements into electronic integrated circuits to convert electrical signals into optical signals for transmission has become an important issue to be solved by those in the industry in order to increase data transmission bandwidth and reduce transmission losses.

### SUMMARY

An aspect of the disclosure is to provide a manufacturing method of a semiconductor device that may efficiently solve the aforementioned problems.

According to an embodiment of the disclosure, a manufacturing method of a semiconductor device includes: providing a first wafer, in which the first wafer includes a first dielectric layer, a first metal layer, and a first optical element, the first metal layer and the first optical element are in the first dielectric layer, and a portion of the first metal layer and a portion of the first optical element are exposed through the first dielectric layer; providing a second wafer, in which the second wafer includes a substrate, a second dielectric layer, and a second metal layer, the second dielectric layer are over the substrate, the second metal layer are in the second dielectric layer, and a portion of the second metal layer is exposed through the second dielectric layer; and docking the first wafer and the second wafer, such that the first dielectric layer is bonded to the second dielectric layer, and the first metal layer is bonded to the second metal layer, in which the first optical element is bonded to the second dielectric layer.

In an embodiment of the disclosure, the portion of the second metal layer protrudes from the second dielectric layer, the first dielectric layer has a recess, and the first wafer and the second wafer are docked, such that the portion of the second metal layer are bonded to the first dielectric layer and in the recess.

In an embodiment of the disclosure, the first wafer and the second wafer are docked, such that the portion of the first metal layer is in contact with the portion of the second metal layer.

In an embodiment of the disclosure, the second wafer further includes a second optical element in the second dielectric layer, and the first wafer and the second wafer are docked, such that the first optical element is coupled to the second optical element.

In an embodiment of the disclosure, the first wafer and the second wafer are docked, such that the first optical element is separated from the second optical element through the second dielectric layer.

In an embodiment of the disclosure, the manufacturing method further includes removing the substrate of the second wafer.

According to another embodiment of the disclosure, a manufacturing method of a semiconductor device includes: forming a first wafer, in which the first wafer includes a first dielectric structure, a first metal interconnect structure, and a first optical element, the first metal interconnect structure and the first optical element are in the first dielectric structure, and a portion of the first metal interconnect structure and a portion of the first optical element are exposed through the first dielectric structure; forming a second wafer, in which the second wafer includes a second dielectric structure, a second metal interconnect structure, and a second optical element, the second metal interconnect structure and the second optical element are in the second dielectric structure, and a portion of the second metal interconnect structure is exposed through the second dielectric structure; and docking the first wafer and the second wafer, such that the first metal interconnect structure is bonded to the second metal interconnect structure, and the first optical element is coupled to the second optical element.

In an embodiment of the disclosure, the first wafer and the second wafer are docked, such that the portion of the first metal interconnect structure is in contact with the portion of the second metal interconnect structure.

In an embodiment of the disclosure, the first wafer and the second wafer are docked, such that the portion of the first optical element is bonded to the second dielectric structure.

In an embodiment of the disclosure, the portion of the second metal interconnect structure protrudes from the second dielectric structure, the first dielectric structure has a recess, and the first wafer and the second wafer are docked, such that the portion of the second metal interconnect structure is bonded to the first dielectric structure and in the recess.

In an embodiment of the disclosure, the second metal interconnect structure further has another portion that is level with the second dielectric structure, and the first wafer and the second wafer are docked, such that the another portion of the second metal interconnect structure is bonded to the portion of the first metal interconnect structure.

In an embodiment of the disclosure, a portion of the second optical element is exposed through the second dielectric structure, and the first wafer and the second wafer are docked, such that the portion of the first optical element is in contact with the portion of the second optical element.

In an embodiment of the disclosure, the first wafer and the second wafer are docked, such that the first optical element is separated from the second optical element through the second dielectric structure.

In an embodiment of the disclosure, after the first wafer and the second wafer are docked, the first optical element is vertically below the second optical element.

In an embodiment of the disclosure, the first wafer further includes a third optical element in the first dielectric structure and electrically connected to the first metal interconnect structure.

In an embodiment of the disclosure, the third optical element is separated from the first optical element through the first dielectric structure.

In an embodiment of the disclosure, a part of the third optical element is vertically below the first optical element.

In an embodiment of the disclosure, forming the second wafer includes: forming the second optical element over a substrate; forming the second dielectric structure over the substrate and covering the second optical element; forming the second metal interconnect structure in the second dielectric structure; disposing a temporary storage substrate over the second dielectric structure; and removing the substrate.

In an embodiment of the disclosure, the second metal interconnect structure is formed after the second optical element is formed.

In an embodiment of the disclosure, forming the second wafer further includes removing at least a portion of the second dielectric structure to expose the portion of the second metal interconnect structure.

Accordingly, in the manufacturing method of the semiconductor device of some embodiments of the present disclosure, by employing hybrid bonding, two wafers that have both electronic integrated circuits and photonic integrated circuits can be bonded together. This approach allows for the use of three-dimensional integrated circuit concepts to integrate and achieve a multi-layer structure (such as an interposer) that supports both transmissions of electrical and optical signals, thereby enhancing the computational performance of the semiconductor device and reducing transmission losses. Furthermore, forming the photonic integrated circuits before the electronic integrated circuits can prevent the high-temperature processes of the photonic integrated circuits from affecting the electrical properties of the electronic integrated circuits.

It is to be understood that both the foregoing general description and the following detailed description are by examples and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1A, FIG. 1B, and FIG. 1C are cross-sectional views of intermediate stages of a manufacturing method of a semiconductor device according to some embodiments of the present disclosure;

FIG. 2A, FIG. 2B, FIG. 2C, and FIG. 2D are cross-sectional views of intermediate stages of a manufacturing method of a semiconductor device according to some embodiments of the present disclosure;

FIG. 3A and FIG. 3B are cross-sectional views of intermediate stages of a manufacturing method of a semiconductor device according to some other embodiments of the present disclosure;

FIG. 4A and FIG. 4B are cross-sectional views of intermediate stages of a manufacturing method of a semiconductor device according to some other embodiments of the present disclosure;

FIG. 5A and FIG. 5B are cross-sectional views of intermediate stages of a manufacturing method of a semiconductor device according to some other embodiments of the present disclosure;

FIG. 6A, FIG. 6B, and FIG. 6C are cross-sectional views of intermediate stages of a manufacturing method of a wafer of a semiconductor device according to some embodiments of the present disclosure; and

FIG. 7A, FIG. 7B, and FIG. 7C are cross-sectional views of intermediate stages of a manufacturing method of a wafer of a semiconductor device according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

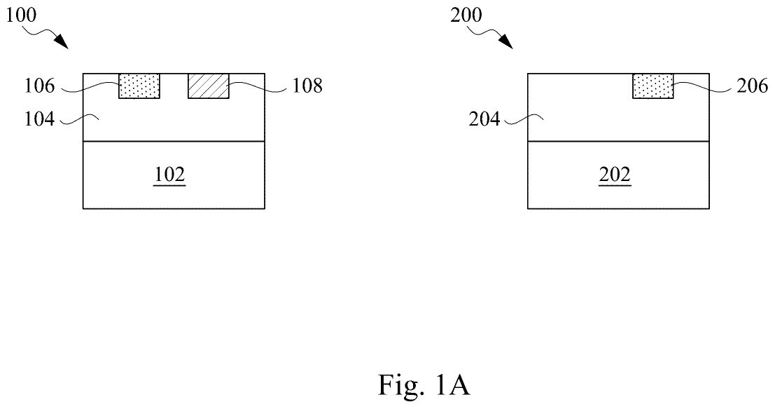

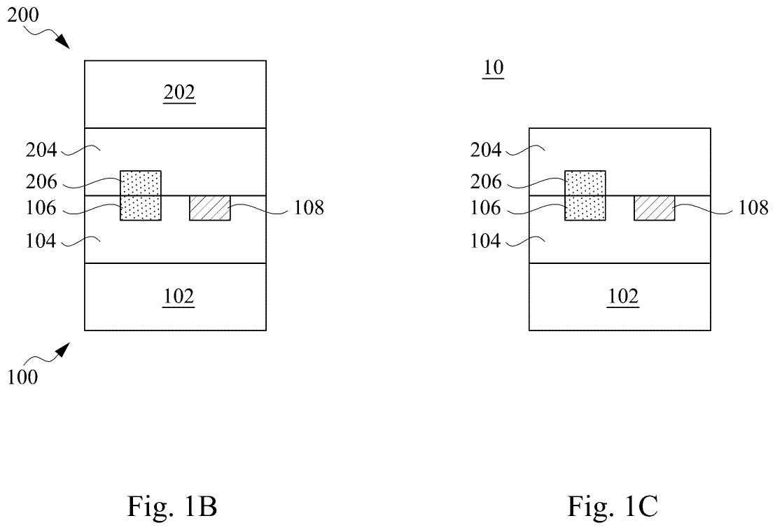

Reference is made to FIG. 1A to FIG. 1C. FIG. 1A to FIG. 1C are cross-sectional views of intermediate stages of a manufacturing method of a semiconductor device 10 according to some embodiments of the present disclosure.

In the manufacturing method of the semiconductor device 10, a wafer 100 and a wafer 200 are firstly provided, as shown in FIG. 1A.

The wafer 100 includes a substrate 102, a dielectric layer 104, a metal layer 106, and an optical element 108. The dielectric layer 104 is over the substrate 102. The metal layer 106 and the optical element 108 are in the dielectric layer 104. A portion of the metal layer 106 is exposed through the dielectric layer 104. In some embodiments, a portion of the optical element 108 is exposed through the dielectric layer 104. In some embodiments, the exposed surface of the metal layer 106, the exposed surface of the optical element 108, and the surface of the dielectric layer 104 are coplanar. In some embodiments, the metal layer 106 may be metal lines, and the optical element 108 may be an optical waveguide structure.

The wafer 200 includes a substrate 202, a dielectric layer 204, and a metal layer 206. The dielectric layer 204 is over the substrate 202. The metal layer 206 is in the dielectric layer 204. A portion of the metal layer 206 is exposed through the dielectric layer 204, and the exposed surface of the portion of the metal layer 206 is coplanar with the surface of the dielectric layer 204.

Then, as shown in FIG. 1B, the wafer 100 and the wafer 200 are docked, such that the dielectric layer 104 is bonded to the dielectric layer 204, the metal layer 106 is bonded to the metal layer 206, and the exposed surface of the optical element 108 is bonded to the surface of the dielectric layer 204. In some embodiments, as shown in FIG. 1B, after the wafer 100 and the wafer 200 are docked, the exposed portion of the metal layer 106 is in contact with the exposed portion of the metal layer 206.

In the present disclosure, the term “bond” may be achieved by hybrid bonding process, such as thermo-compression bonding (TCB), direct bonding, fusion bonding, transient liquid phase (TLP) bonding, surface activated bonding (SAB), or the like. In some embodiments, there may be auxiliary bonding substances between the two components or materials being bonded, such as polymers, oxides, glass, or metals used as adhesives. In other embodiments, the two components or materials being bonded are in direct contact.

Then, as shown in FIG. 1C, the manufacturing method includes removing the substrate 202 of the wafer 200. The remaining structure forms the semiconductor device 10.

The manufacturing method of the semiconductor device of the present disclosure is applicable to various components, which includes, but is not limited to, fan-out packaging components, interposer-related components, components related to hybrid bonding, high-bandwidth memory devices, high-performance computing chips, high-end graphics cards, co-packaged optical elements. The advantages of this manufacturing method lie in its ability to effectively integrate optical elements into traditional semiconductor devices, thereby enhancing the efficiency and speed of data transmission. The introduction of optical elements not only increases the bandwidth of data transmission but also reduces losses during the transmission process, which is particularly important for applications requiring high-speed data transfer. Additionally, this manufacturing method can increase the integration density of semiconductor devices, allowing them to achieve more functions in a smaller space.

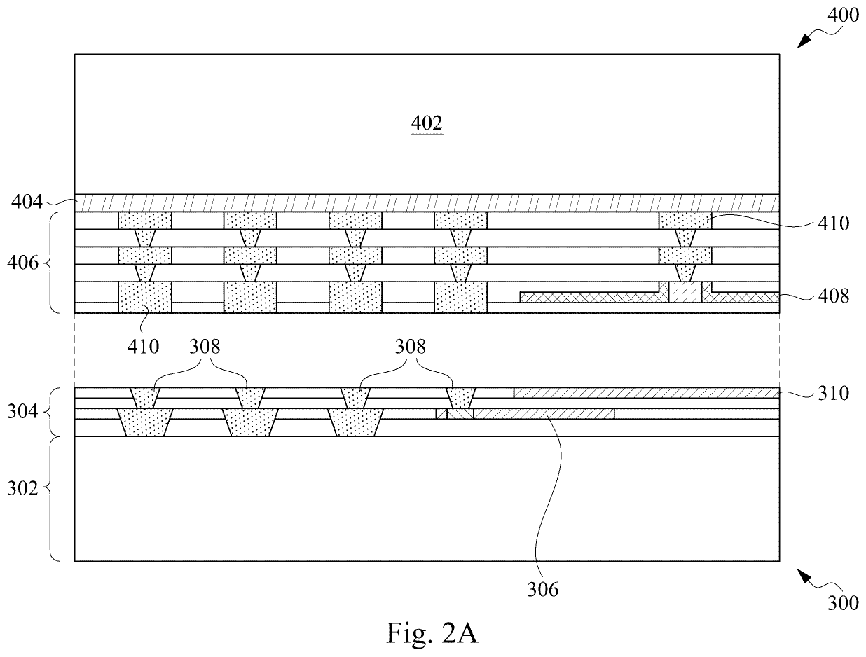

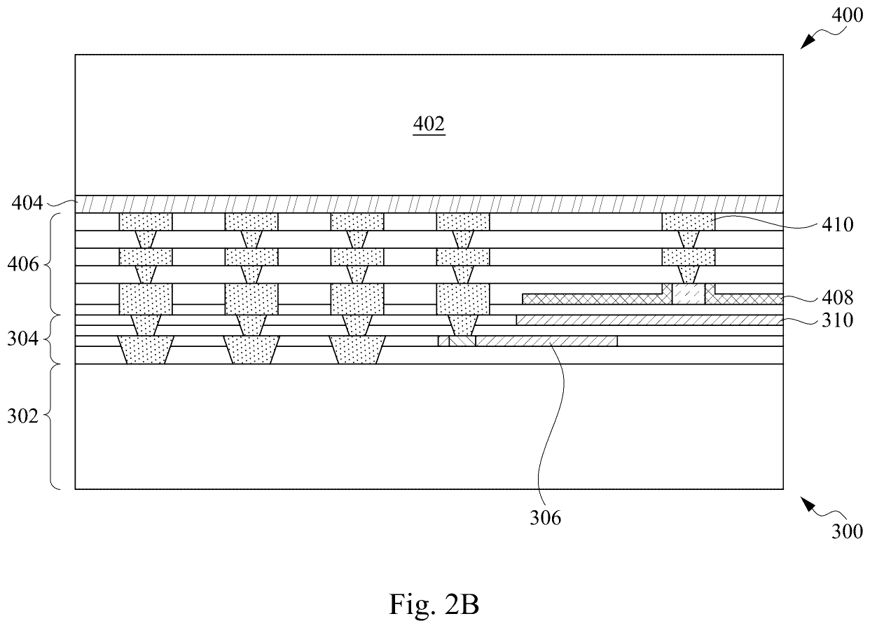

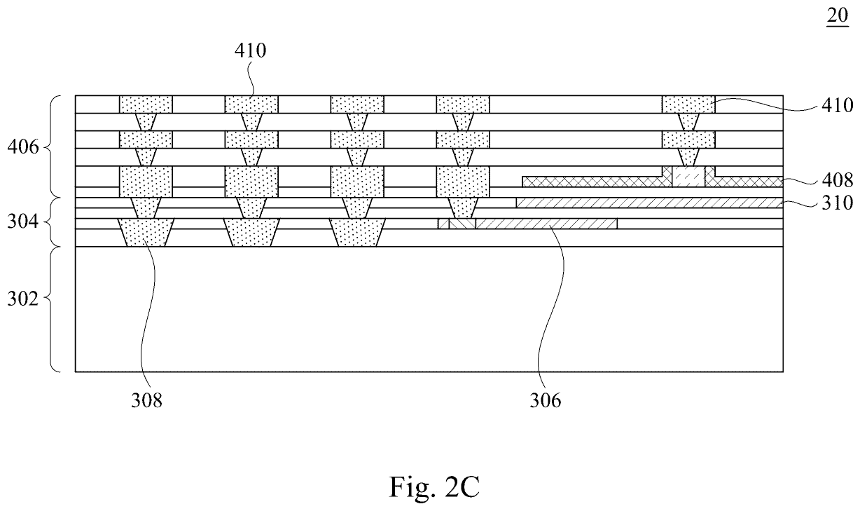

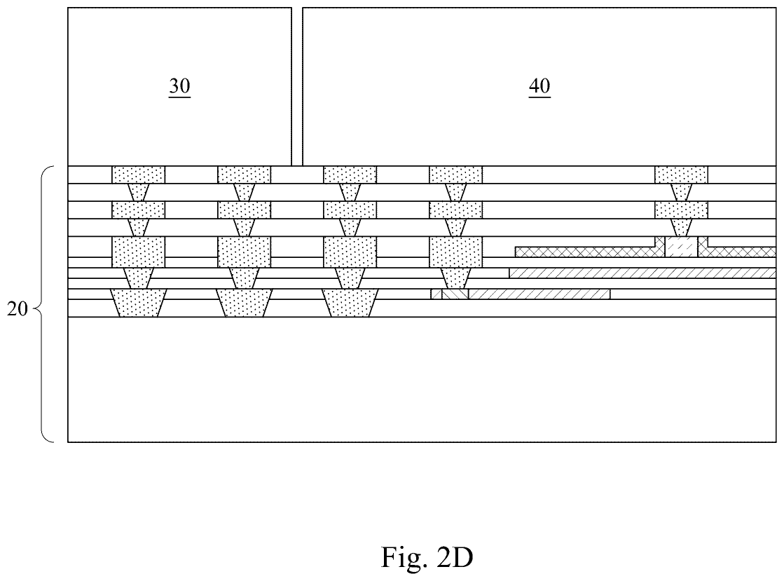

Reference is made to FIG. 2A to FIG. 2D. FIG. 2A to FIG. 2D are cross-sectional views of intermediate stages of a manufacturing method of a semiconductor device 20 according to some embodiments of the present disclosure. It should be noted that the semiconductor device 20 is an interposer including metal interconnect structures, active optical elements, and passive optical elements.

Similarly, in the manufacturing method of the semiconductor device 20, the wafer 300 and the wafer 400 are firstly provided, as shown in FIG. 2A.

The wafer 300 includes a substrate 302, a dielectric structure 304, an optical element 306, a metal interconnect structure 308, and an optical element 310. The dielectric structure 304 is over the substrate 302, and the optical element 306, the metal interconnect structure 308, and the optical element 310 are in the dielectric structure 304. The metal interconnect structure 308 and the optical element 310 are partially exposed through the dielectric structure 304, and the exposed surface of the metal interconnect structure 308, the exposed surface of the optical element 310, and the surface of the dielectric structure 304 are coplanar. In some embodiments, the metal interconnect structure 308 is partially in contact with the optical element 306. In some embodiments, the optical element 306 is an active component such as an infrared photodiode (IR photodiode), which is configured to detect infrared light signals and convert them into electrical signals. The optical element 310 is an optical waveguide structure. A part of the optical element 306 is vertically below the optical element 310 and is optically coupled to the optical element 310. The optical element 306 is separated from the optical element 310 through the dielectric structure 304.

The wafer 400 (shown inverted in FIG. 2A) includes a substrate 402, a dielectric structure 406, an optical element 408, and a metal interconnect structure 410. The dielectric structure 406 is over the substrate 402, and the optical element 408 and the metal interconnect structure 410 are in the dielectric structure 406. The metal interconnect structure 410 is partially exposed though the dielectric structure 406, and the exposed surface of the metal interconnect structure 410 is coplanar with the surface of the dielectric structure 406. In some embodiments, the dielectric structure 406 and the metal interconnect structure 410 are connected to the substrate 402 through an adhesive layer 404. The optical element 408 is on a side of the dielectric structure 406 that is away from the substrate 402. In some embodiments, the optical element 408 includes a passive component, such as an optical waveguide structure, and an active component, such as an optical modulator, which is configured to control the transmission of light.

Then, the wafer 300 and the wafer 400 are docked, as shown in FIG. 2B, such that the metal interconnect structure 308 is bonded to the metal interconnect structure 410, and the optical element 310 is optically coupled to the optical element 408. Meanwhile, the dielectric structure 304 is bonded to the dielectric structure 406. In some embodiments, the exposed surface of the metal interconnect structure 308 is in contact with the exposed surface of the metal interconnect structure 410 and is bonded to the exposed surface of the metal interconnect structure 410. In some embodiments, the exposed surface of the optical element 310 is bonded to the surface of the dielectric structure 406. As such, the optical element 310 is separated from the optical element 408 through the dielectric structure 406. In addition, the wafer 300 and the wafer 400 are docked, such that the optical element 310 is vertically below the optical element 408. In this way, when the optical element 408 allows light to pass through, the light can be transmitted vertically to the optical element 310. Then, the light can be transmitted to the optical element 306 where it is converted into an electrical signal. Then, the electrical signal can be transmitted to portions of the metal interconnect structure 308 and the metal interconnect structure 410.

Then, as shown in FIG. 2C, the substrate 402 of the wafer 400 and the adhesive layer 404 are removed. The remaining structure then forms the semiconductor device 20.

In some embodiments, as shown in FIG. 2D, a high-bandwidth memory 30 (HBM) can be stacked and connected to the semiconductor device 20 along with an application-specific integrated circuit 40 (ASIC) to achieve interconnection between the high-bandwidth memory 30 and the application-specific integrated circuit 40.

In the manufacturing methods of the semiconductor device 10 and the semiconductor device 20, two wafers to be docked may be formed with different features according to the bonding requirements. A detailed explanation of the bonding of two wafers with different features will be provided accompanied by the drawings in the following paragraphs.

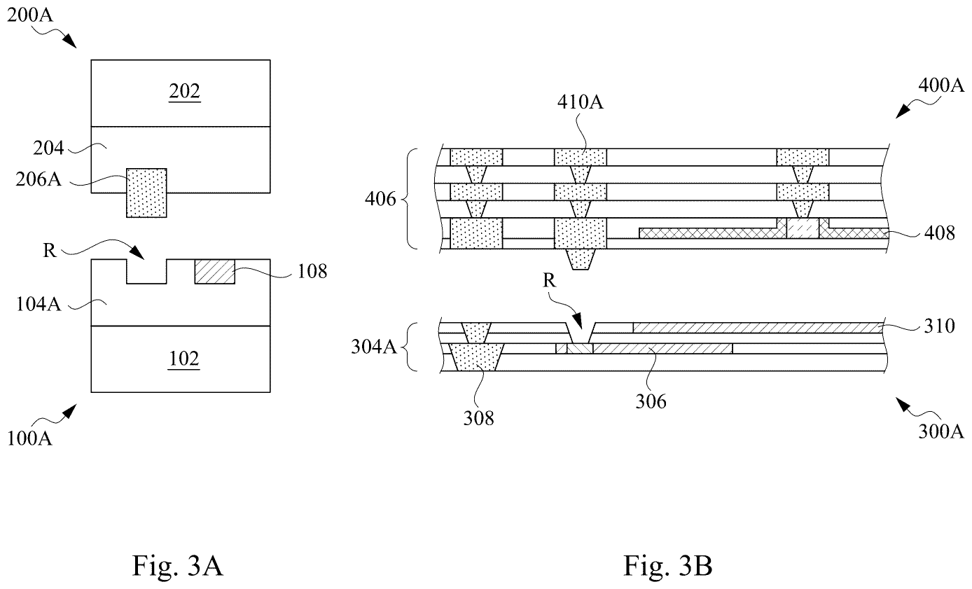

Reference is made to FIG. 3A and FIG. 3B. FIG. 3A and FIG. 3B are cross-sectional views of intermediate stages of the manufacturing method of the semiconductor device 10 and the semiconductor device 20 according to some other embodiments of the present disclosure. As shown in FIG. 3A, a wafer 100A and a wafer 200A are docked, in which the dielectric layer 104A of the wafer 100A has a recess R at the position corresponding to the metal layer 106 in FIG. 1A. Meanwhile, the metal layer 206A of the wafer 200A may protrude from the surface of the dielectric layer 204. Then, the wafer 100A and the wafer 200A are docked, so that the metal layer 206A is bonded to the dielectric layer 104A and the protruding portion of the metal layer 206A is inserted into the recess R.

Similarly, as shown in FIG. 3B, the wafer 300A and the wafer 400A are provided for docking, in which the dielectric structure 304A of the wafer 300A has a recess R. The recess R may expose a portion of the optical element 306. Meanwhile, the metal interconnect structure 410A of the wafer 400A has a portion that is exposed and level with the surface of the dielectric structure 406. Also, the metal interconnect structure 410A of the wafer 400A has another portion that is exposed and protruding from the surface of the dielectric structure 406. Then, the wafer 300A and the wafer 400A are docked, such that the dielectric structure 304A is bonded to the dielectric structure 406, the metal interconnect structure 308 is bonded to the metal interconnect structure 410A, and the optical element 310 is optically coupled to the optical element 408. In greater detail, the wafer 300A and the wafer 400A are docked, so that the portion of the metal interconnect structure 410A that is level with the dielectric structure 406 is bonded to the exposed surface of the metal interconnect structure 308. The protruding portion of the metal interconnect structure 410A is bonded to the dielectric structure 304A and is inserted into the recess R. The protruding portion of the metal interconnect structure 410A may be in contact with the optical element 306 and is electrically connected to the optical element 306. In addition, the optical element 310 is separated from the optical element 408 through the dielectric structure 406.

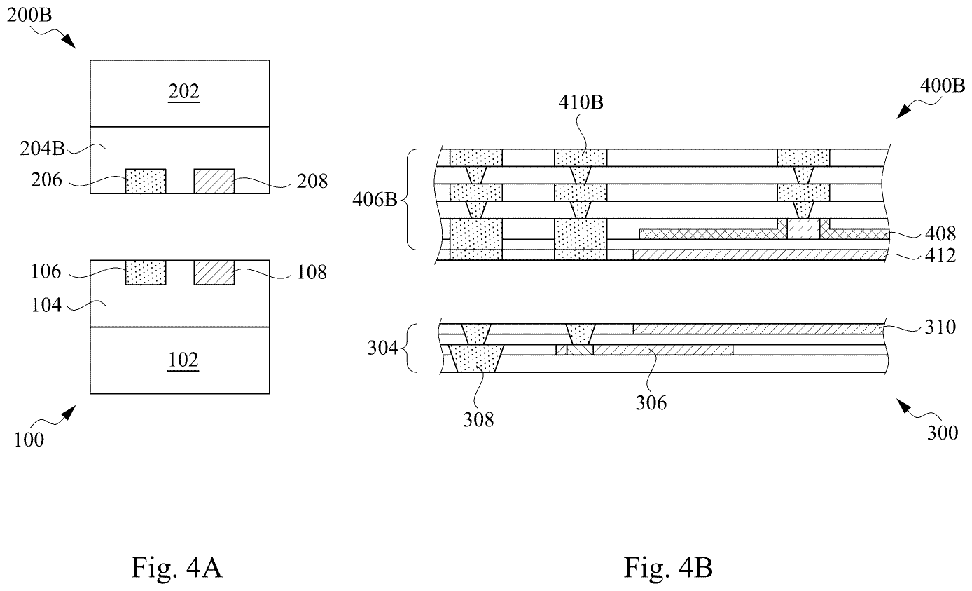

Reference is made to FIG. 4A and FIG. 4B. FIG. 4A and FIG. 4B are cross-sectional views of intermediate stages of the manufacturing method of the semiconductor device 10 and the semiconductor device 20 according to some other embodiments of the present disclosure. As shown in FIG. 4A, the wafer 100 and a wafer 200B are docked, in which the wafer 200B further includes the optical element 208 is in the dielectric layer 204B and the optical element 208 is partially exposed through the dielectric layer 204B. The exposed surface of the optical element 208 is coplanar with the exposed surface of the metal layer 206 and the surface of the dielectric layer 204B. Then, the wafer 100 and the wafer 200B are docked, so that the exposed surface of the optical element 208 is in contact with the exposed surface of the optical element 108 and is bonded to the exposed surface of the optical element 108. The optical element 108 and the optical element 208 are optically coupled to each other.

Similarly, as shown in FIG. 4B, the wafer 300 and the wafer 400B are provided for docking, in which the wafer 400B further includes an optical element 412 in the dielectric structure 406B and partially exposed through the dielectric structure 406B. The exposed surface of the optical element 412, the exposed surface of the metal interconnect structure 410B, and the surface of the dielectric structure 406B are coplanar. Then, the wafer 300 and the wafer 400B are docked, such that the dielectric structure 304 is bonded to the dielectric structure 406B, the metal interconnect structure 308 is bonded to the metal interconnect structure 410B, and the optical element 310 is optically coupled to the optical element 412. In greater detail, the wafer 300 and the wafer 400B are docked, so that the exposed surface of the metal interconnect structure 410B is bonded to the exposed surface of the metal interconnect structure 308, and the exposed surface of the optical element 412 is in contact with the exposed surface of the optical element 310 and is bonded to the exposed surface of the optical element 310. In some embodiments, the optical element 412 and the optical element 310 may be optical waveguide structures.

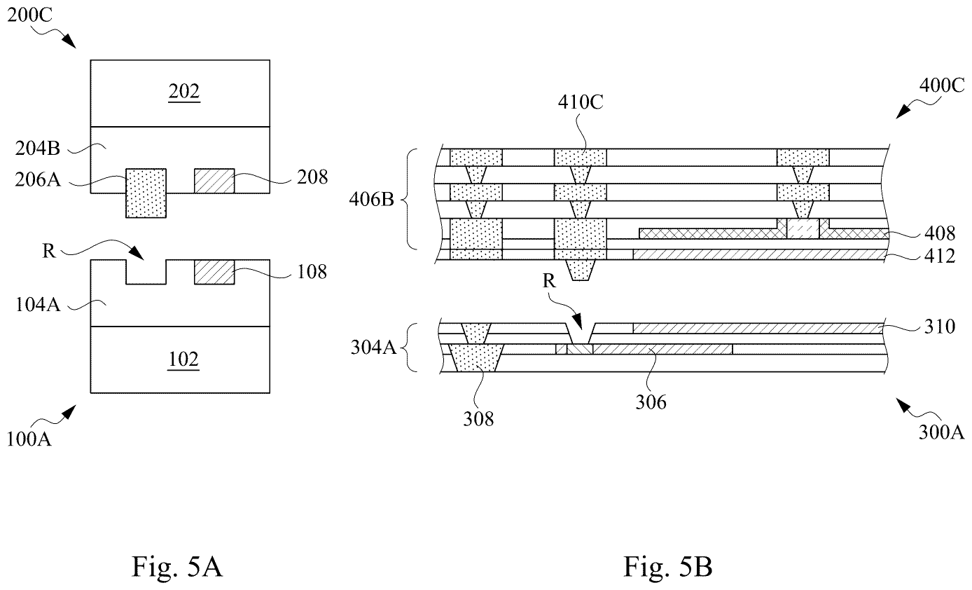

Reference is made to FIG. 5A and FIG. 5B. FIG. 5A and FIG. 5B are cross-sectional views of intermediate stages of the manufacturing method of the semiconductor device 10 and the semiconductor device 20 according to some other embodiments of the present disclosure. As shown in FIG. 5A, the wafer 100A and the wafer 200C are provided for docking, in which the wafer 200C combines the features of the wafer 200A and the wafer 200B, such that the wafer 200C has the metal layer 206A protruding from the dielectric layer 204B and the optical element 208 that is in the dielectric layer 204B and is partially exposed. It should be noted that the surface of the optical element 208 is level with the surface of the dielectric layer 204B. Then, the wafer 100A and the wafer 200C are docked, so that the metal layer 206A is bonded to the dielectric layer 104A, the protruding portion of the metal layer 206A is inserted into the recess R, and the exposed surface of the optical element 208 is in contact with the exposed surface of the optical element 108 and is bonded to the exposed surface of the optical element 108. The optical element 108 and the optical element 208 are optically coupled to each other.

Similarly, as shown in FIG. 5B, the wafer 300A and the wafer 400C are provided for docking, in which the wafer 400C combines the features of the wafer 400A and the wafer 400B, such that the wafer 400C has the metal interconnect structure 410C protruding from the dielectric structure 406B and the optical element 412 that is in the dielectric structure 406B and is partially exposed. Then, the wafer 300A and the wafer 400C are docked, so that the dielectric structure 304A is bonded to the dielectric structure 406B, the metal interconnect structure 308 is bonded to the metal interconnect structure 410C, and the optical element 310 is optically coupled to the optical element 412. In greater detail, the wafer 300A and the wafer 400C are docked, so that the portion of the metal interconnect structure 410C that is level with the dielectric structure 406B is bonded to the exposed surface of the metal interconnect structure 308, the protruding portion of the metal interconnect structure 410C is bonded to the dielectric structure 304A and inserted into the recess R, and the exposed surface of the optical element 412 is bonded to the exposed surface of the optical element 310.

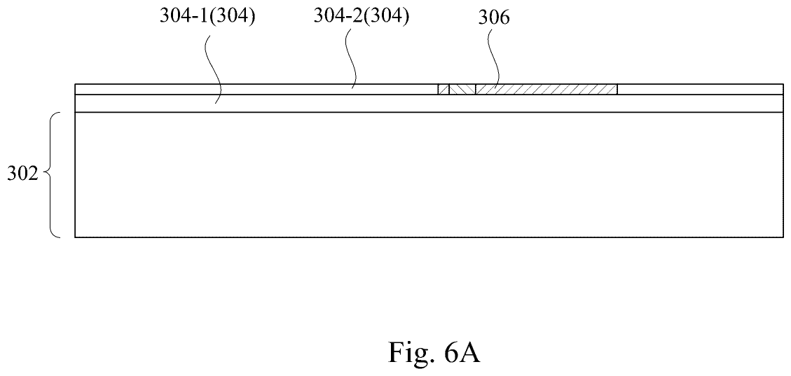

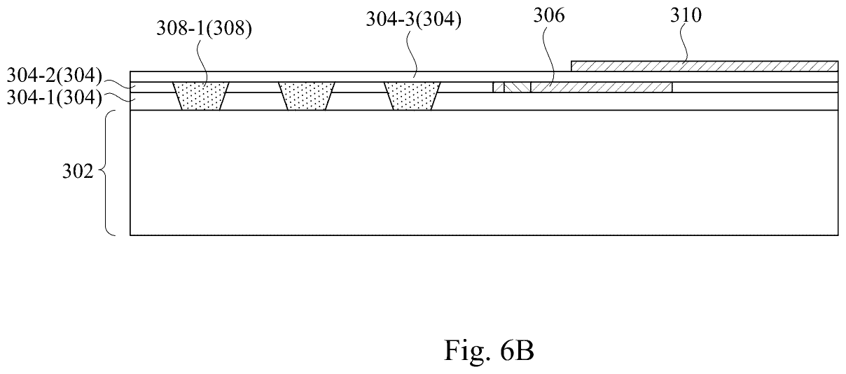

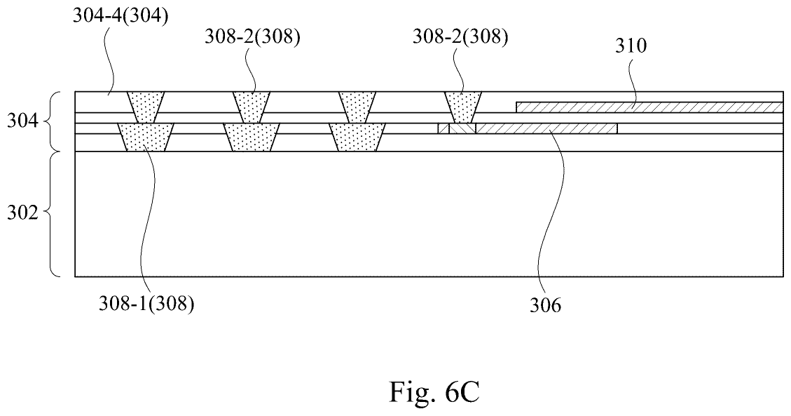

FIG. 6A to FIG. 6C are cross-sectional views of intermediate stages of a manufacturing method of the wafer 300 of the semiconductor device 20 according to some embodiments of the present disclosure. Steps for forming the wafer 300 according to some embodiments will be illustrated accompanied with the drawings in the following paragraphs.

First, as shown in FIG. 6A, the optical element 306 is formed over the substrate 302. In some embodiments, there is a dielectric layer 304-1 disposed between the optical element 306 and the substrate 302. This step may be achieved by processing a silicon-on-insulator (SOI) wafer. For example, the silicon substrate of the SOI wafer acts as the substrate 302, the buried oxide layer (BOX layer) of the SOI wafer acts as the dielectric layer 304-1, and the top silicon layer of the SOI wafer is processed to be the optical element 306. As aforementioned, in some embodiments, the optical element 306 may be an active component, such as an infrared photodiode. Then, a dielectric layer 304-2 is formed over the dielectric layer 304-1 and laterally surrounding the optical element 306.

Then, as shown in FIG. 6B, a metal layer 308-1 is formed in the dielectric layer 304-1 and the dielectric layer 304-2. The metal layer 308-1 is on a side of the optical element 306, and a bottom surface of the metal layer 308-1 may be lower than a bottom surface of the optical element 306. In some embodiments, the bottom surface of the metal layer 308-1 is in contact with the substrate 302. Then, the dielectric layer 304-3 is formed over the dielectric layer 304-2 and covering the metal layer 308-1 and the optical element 306. Next, the optical element 310 is formed over the dielectric layer 304-3. The optical element 310 is over the optical element 306 and is not over the metal layer 308-1. In other words, an orthographic projection area of the optical element 310 projected onto the substrate 302 overlaps an orthographic projection area of the optical element 306 projected onto the substrate 302 and is separated from an orthographic projection area of the metal layer 308-1 projected onto the substrate 302. As aforementioned, in some embodiments, the optical element 310 may be an optical waveguide structure including silicon nitride. In some embodiments, forming the optical element 310 includes forming a silicon nitride layer covering the dielectric layer 304-3 and patterning the silicon nitride layer through a photoresist (not shown).

Then, as shown in FIG. 6C, a dielectric layer 304-4 is formed covering the optical element 310 and the dielectric layer 304-3. Next, a metal layer 308-2 is formed in the dielectric layer 304-3 and the dielectric layer 304-4. The metal layer 308-2 is on a side of the optical element 310. The metal layer 308-2 has multiple portions over the metal layer 308-1 and connected to the metal layer 308-1. The metal layer 308-2 further has another portion that is over the optical element 306, in contact with the optical element 306, and electrically connected to the optical element 306. The metal layer 308-2 is partially exposed through the dielectric layer 304-4.

Next, a planarization process is performed to the metal layer 308-2 and the dielectric layer 304-4 to expose the surface of the optical element 310 and to make the surface of the optical element 310, the surface of the metal layer 308-2, and the surface of the dielectric layer 304-4 are coplanar, forming the wafer 300 as shown in FIG. 2A. The metal layer 308-1 and the metal layer 308-2 may be collectively referred to as the metal interconnect structure 308. The dielectric layer 304-1, the dielectric layer 304-2, the dielectric layer 304-3, and the dielectric layer 304-4 may be collectively referred to as the dielectric structure 304.

In some embodiments, the substrate 302 may include a silicon substrate, a glass substrate, a steel substrate, an organic substrate, or other suitable substrates. The dielectric structure 304 may include a silicon-based material such as silicon oxide, an organic material, or other suitable materials. In some embodiments, the metal interconnect structure 308 may include a conductive material such as gold (Au), copper (Cu), silver (Ag), nickel (Ni), titanium (Ti), tin (Sn), molybdenum (Mo), tantalum (Ta), cobalt (Co), ruthenium (Ru), a soldering material, or other suitable materials. In some embodiments, the optical element 306 and the optical element 310 may include a silicon-based material, an organic material, or other suitable materials. For example, the optical element 306 may include silicon, and the optical element 310 may include silicon nitride. In some embodiments, a refractive index of the material of the dielectric structure 304 is less than a refractive index of the material of the optical element 310.

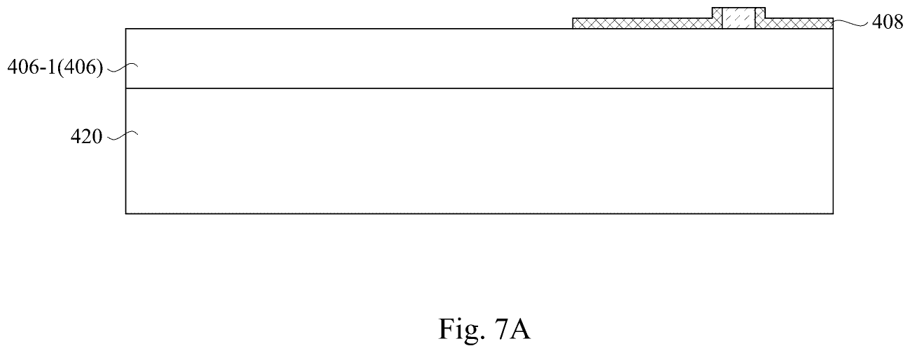

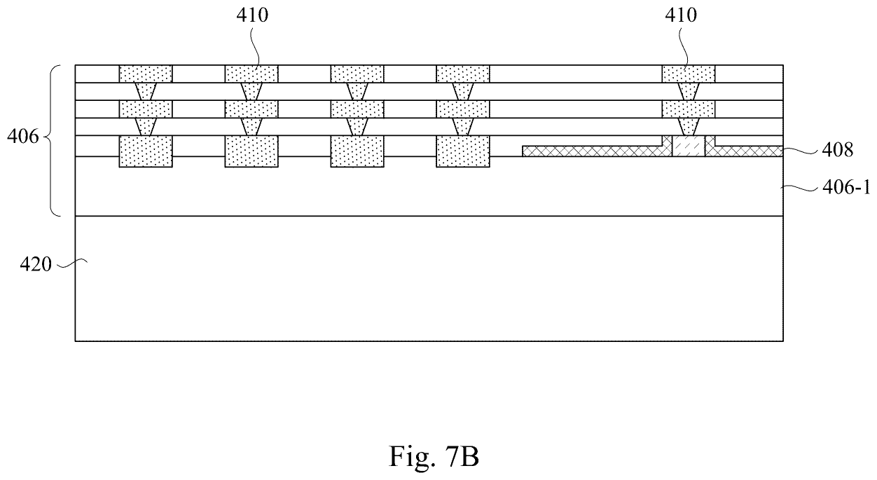

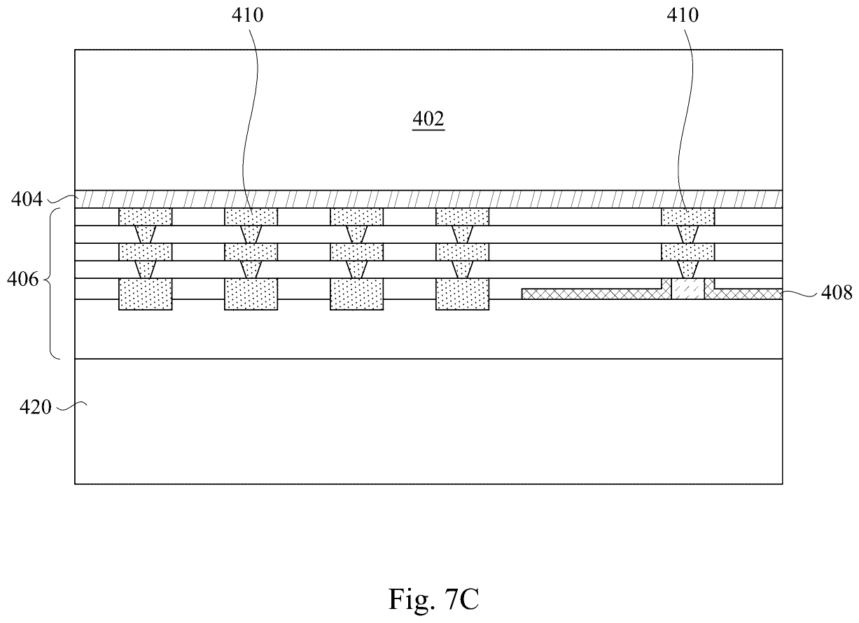

FIG. 7A to FIG. 7C are cross-sectional views of intermediate stages of the manufacturing method of the wafer 400 of the semiconductor device 20 according to some embodiments of the present disclosure. Steps for forming the wafer 400 according to some embodiments will be illustrated accompanied with the drawings in the following paragraphs.

First, as shown in FIG. 7A, the optical element 408 is formed over the substrate 420. In some embodiments, there is a dielectric layer 406-1 disposed between the optical element 408 and the substrate 420. Similarly, this step may be achieved by processing a SOI wafer. For example, the silicon substrate of the SOI wafer acts as the substrate 420, the buried oxide layer of the SOI wafer acts as the dielectric layer 406-1, and the top silicon layer of the SOI wafer is processed to be the optical element 408. As aforementioned, in some embodiments, the optical element 408 includes a passive component, such as an optical waveguide structure, and an active component, such as an optical modulator.

Then, as shown in FIG. 7B, similar to the steps for forming the wafer 300, multiple dielectric layers and metal layers are sequentially formed and stacked after the optical element 408 is formed. As a result, the dielectric structure 406 is formed over the substrate 420 and covering the optical element 408, and the metal interconnect structure 410 is formed in the dielectric structure 406, as shown in FIG. 7B. In addition, the metal interconnect structure 410 has multiple portions that are over the optical element 408, in contact with the optical element 408, and electrically connected to the optical element 408.

Next, as shown in FIG. 7C, the substrate 402 is disposed over the dielectric structure 406. To be more specific, the metal interconnect structure 410 and the dielectric structure 406 are connected to the substrate 402 through the adhesive layer 404. In some embodiments, the substrate 402 acts as a temporary storage substrate and may be a carrier wafer.

Then, the substrate 420 is removed by processes such as grinding, and then a portion of the dielectric layer 406-1 is removed by processes such as chemical mechanical polishing (CMP) to expose the surface of the metal interconnect structure 410 that is away from the substrate 402, forming the wafer 400 shown in FIG. 2A.

Similarly, in some embodiments, the substrate 402 and the substrate 420 may include a silicon substrate, a glass substrate, a steel substrate, an organic substrate, or other suitable substrates. The dielectric structure 406 may include a silicon-based material such as silicon oxide, an organic material, or other suitable materials. In some embodiments, the metal interconnect structure 410 may include a conductive material such as gold (Au), copper (Cu), silver (Ag), nickel (Ni), titanium (Ti), tin (Sn), molybdenum (Mo), tantalum (Ta), cobalt (Co), ruthenium (Ru), a soldering material, or other suitable materials. In some embodiments, the optical element 408 may include a silicon-based material, an organic material, or other suitable materials. For example, the optical element 408 may include silicon.

In the aforementioned steps for forming the wafer 300 and the wafer 400, since the optical element is formed before forming the metal interconnect structure, the electrical properties of the metal interconnect structure can be prevented from being damaged by the high-temperature processes for forming the optical element.

Accordingly, in the manufacturing method of the semiconductor device of some embodiments of the present disclosure, by employing hybrid bonding, two wafers that have both electronic integrated circuits and photonic integrated circuits can be bonded together. This approach allows for the use of three-dimensional integrated circuit concepts to integrate and achieve a multi-layer structure (such as an interposer) that supports both transmissions of electrical and optical signals, thereby enhancing the computational performance of the semiconductor device and reducing transmission losses. Furthermore, forming the photonic integrated circuits before the electronic integrated circuits can prevent the high-temperature processes of the photonic integrated circuits from affecting the electrical properties of the electronic integrated circuits.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A manufacturing method of a semiconductor device, comprising:
providing a first wafer, wherein the first wafer comprises a first dielectric layer, a first metal layer, and a first optical element, the first metal layer and the first optical element are in the first dielectric layer, and a portion of the first metal layer and a portion of the first optical element are exposed through the first dielectric layer;
providing a second wafer, wherein the second wafer comprises a substrate, a second dielectric layer, and a second metal layer, the second dielectric layer are over the substrate, the second metal layer are in the second dielectric layer, and a portion of the second metal layer is exposed through the second dielectric layer; and
docking the first wafer and the second wafer, such that the first dielectric layer is bonded to the second dielectric layer, and the first metal layer is bonded to the second metal layer, wherein the first optical element is bonded to the second dielectric layer.

2. The manufacturing method of claim 1, wherein the portion of the second metal layer protrudes from the second dielectric layer, the first dielectric layer has a recess, and the first wafer and the second wafer are docked, such that the portion of the second metal layer is bonded to the first dielectric layer and in the recess.

3. The manufacturing method of claim 1, wherein the first wafer and the second wafer are docked, such that the portion of the first metal layer is in contact with the portion of the second metal layer.

4. The manufacturing method of claim 1, wherein the second wafer further comprises a second optical element in the second dielectric layer, and the first wafer and the second wafer are docked, such that the first optical element is coupled to the second optical element.

5. The manufacturing method of claim 4, wherein the first wafer and the second wafer are docked, such that the first optical element is separated from the second optical element through the second dielectric layer.

6. The manufacturing method of claim 1, further comprising removing the substrate of the second wafer.

7. A manufacturing method of a semiconductor device, comprising:
forming a first wafer, wherein the first wafer comprises a first dielectric structure, a first metal interconnect structure, and a first optical element, the first metal interconnect structure and the first optical element are in the first dielectric structure, and a portion of the first metal interconnect structure and a portion of the first optical element are exposed through the first dielectric structure;
forming a second wafer, wherein the second wafer comprises a second dielectric structure, a second metal interconnect structure, and a second optical element, the second metal interconnect structure and the second optical element are in the second dielectric structure, and a portion of the second metal interconnect structure is exposed through the second dielectric structure; and
docking the first wafer and the second wafer, such that the first metal interconnect structure is bonded to the second metal interconnect structure, and the first optical element is coupled to the second optical element.

8. The manufacturing method of claim 7, wherein the first wafer and the second wafer are docked, such that the portion of the first metal interconnect structure is in contact with the portion of the second metal interconnect structure.

9. The manufacturing method of claim 7, wherein the first wafer and the second wafer are docked, such that the portion of the first optical element is bonded to the second dielectric structure.

10. The manufacturing method of claim 7, wherein the portion of the second metal interconnect structure protrudes from the second dielectric structure, the first dielectric structure has a recess, and the first wafer and the second wafer are docked, such that the portion of the second metal interconnect structure is bonded to the first dielectric structure and in the recess.

11. The manufacturing method of claim 10, wherein the second metal interconnect structure further has another portion that is level with the second dielectric structure, and the first wafer and the second wafer are docked, such that the another portion of the second metal interconnect structure is bonded to the portion of the first metal interconnect structure.

12. The manufacturing method of claim 7, wherein a portion of the second optical element is exposed through the second dielectric structure, and the first wafer and the second wafer are docked, such that the portion of the first optical element is in contact with the portion of the second optical element.

13. The manufacturing method of claim 7, wherein the first wafer and the second wafer are docked, such that the first optical element is separated from the second optical element through the second dielectric structure.

14. The manufacturing method of claim 7, wherein after the first wafer and the second wafer are docked, the first optical element is vertically below the second optical element.

15. The manufacturing method of claim 7, wherein the first wafer further comprises a third optical element in the first dielectric structure and electrically connected to the first metal interconnect structure.

16. The manufacturing method of claim 15, wherein the third optical element is separated from the first optical element through the first dielectric structure.

17. The manufacturing method of claim 15, wherein a part of the third optical element is vertically below the first optical element.

18. The manufacturing method of claim 7, wherein forming the second wafer comprises:
forming the second optical element over a substrate;
forming the second dielectric structure over the substrate and covering the second optical element;
forming the second metal interconnect structure in the second dielectric structure;
disposing a temporary storage substrate over the second dielectric structure; and
removing the substrate.

19. The manufacturing method of claim 18, wherein the second metal interconnect structure is formed after the second optical element is formed.

20. The manufacturing method of claim 18, wherein forming the second wafer further comprises removing at least a portion of the second dielectric structure to expose the portion of the second metal interconnect structure.
